(19) United States
(12) Patent Application Publication
(10) Pub. No.: US 2026/0006863 A1
(43) Pub. Date: Jan. 1, 2026

(54) SEMICONDUCTOR DEVICE AND MANUFACTURING METHOD THEREOF

(71) Applicant: Hon Young Semiconductor Corporation, Hsinchu City (TW)

(72) Inventor: Yan-Ru CHEN, Hsinchu City (TW)

(21) Appl. No.: 18/800,150

(22) Filed: Aug. 12, 2024

(30) Foreign Application Priority Data
Jul. 1, 2024 (TW) 113124533

(51) Int. Cl. H01L 29/06; H01L 29/10; H01L 29/66; H01L 29/78

(52) U.S. Cl. CPC H10D 62/102; H10D 30/0291; H10D 30/051; H10D 30/665; H10D 62/393

(57) ABSTRACT

A semiconductor device includes a substrate, a drift region, a well region, a first shield region, a junction gate field-effect transistor (JFET) region, a source region and a gate structure. The first shield region is located in the drift region, in which a bottom surface of the first shield region is lower than a bottom surface of the well region and a carrier concentration of the first shield region is greater than a carrier concentration of the well region. The JFET region is located in the drift region, in which a bottom surface of the JFET region is lower than a bottom surface of the first shield region. A first portion of the first shield region is located between the well region and the JFET region. The source region is adjacent to the well region. The gate structure is located on the drift region.

### RELATED APPLICATIONS

This application claims priority to Taiwan Application Serial Number 113124533, filed Jul. 1, 2024, which is herein incorporated by reference.

### BACKGROUND

### Field of Invention

The present disclosure relates to a semiconductor device and a manufacturing method of a semiconductor device.

### Description of Related Art

The industry of semiconductor has grown fast recently, which makes the size of semiconductor device gets smaller and smaller. While the design depth of well region is getting shallower (less than one micrometer), drain-source leakage current (loss) often becomes a major problem in semiconductor components. Thus, the need of a semiconductor component that can solve the problem of drain-source leakage current exists.

### SUMMARY

One aspect of the present disclosure provides a semiconductor device.

According to one embodiment of the present disclosure, a semiconductor device includes a substrate, a drift region, a well region, a first shield region, a junction gate field-effect transistor (JFET) region, a source region and a gate structure. The drift region is located in the substrate. The well region is located in the drift region. The first shield region is located in the drift region, in which a bottom surface of the first shield region is lower than a bottom surface of the well region and a carrier concentration of the first shield region is greater than a carrier concentration of the well region. The JFET region is located in the drift region, in which a bottom surface of the JFET region is lower than a bottom surface of the first shield region, a first portion of the first shield region is located between the well region and the JFET region. The source region is adjacent to the well region. The gate structure is located on the drift region.

Another aspect of the present disclosure provides a semiconductor device.

According to one embodiment of the present disclosure, a semiconductor device includes a substrate, a gate structure, a plurality of well region, a plurality of first shield region, a plurality of second shield region, a junction gate field-effect transistor (JFET) region and a source region. The gate structure is located on the substrate. The well region is located in the substrate and at two sides of the gate structure. The first shield region is located in the substrate and at two sides of the gate structure, in which a bottom surface of the first shield region is lower than a bottom surface of the well region and a carrier concentration of the first shield region is greater than a carrier concentration of the well region. The second shield region is located in the substrate and at two sides of the gate structure, in which a bottom surface of the second shield region is lower than a bottom surface of the first shield region and a carrier concentration of the second shield region is greater than a carrier concentration of the first shield region. The JFET region is located in the substrate, in which a bottom surface of the JFET region is lower than a bottom surface of the second shield region. The source region is adjacent to the well region.

Another aspect of the present disclosure provides a manufacturing method of a semiconductor device.

According to one embodiment of the present disclosure, a manufacturing method of a semiconductor device includes forming a drift region in a substrate; forming a first shield region in the drift region; forming a second shield region in the drift region, in which a carrier concentration of the first shield region is greater than a carrier concentration of the second shield region; forming a well region in the drift region, in which the carrier concentration of the second shield region is greater than a carrier concentration of the well region; forming a source region in the well region; forming a junction gate field-effect transistor (JFET) region in the drift region; and forming a gate structure on the drift region.

In the aforementioned embodiments of the present disclosure, since there are shield regions between the JFET region and well region, the problem of drain-source leakage current can be significantly solved, which decrease the effect of the drain-source leakage current on the power consumption of the device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 to FIG. 4 are cross-sectional views of a semiconductor device during intermediate stages of manufacturing according to one embodiment of the present disclosure.

FIG. 5 is a cross-sectional view of a semiconductor device according to another embodiment of the present disclosure.

FIG. 6 is a cross-sectional view of a semiconductor device according to yet another embodiment of the present disclosure.

FIG. 7 is a cross-sectional view of a semiconductor device according to yet another embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

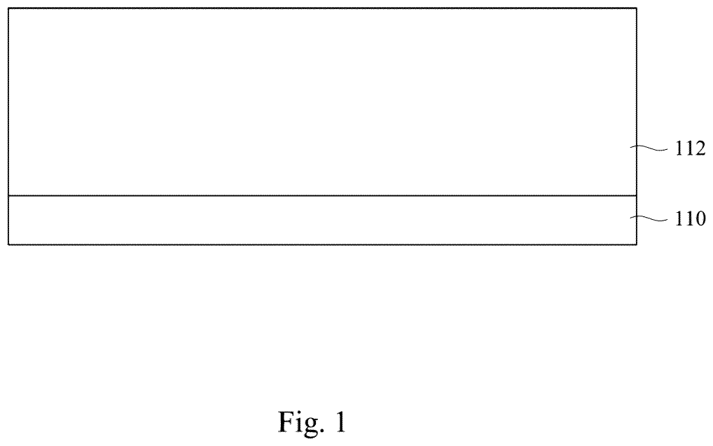

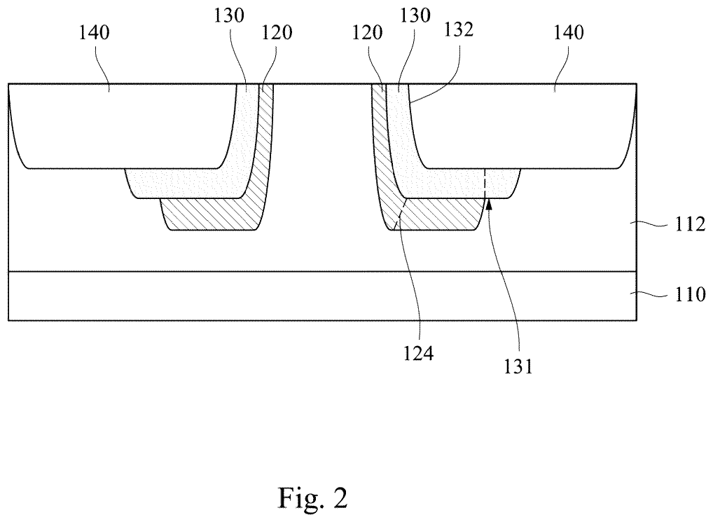

FIG. 1 to FIG. 4 are cross-sectional views of a semiconductor device 100 during intermediate stages of manufacturing according to one embodiment of the present disclosure. Refer to FIG. 1 and FIG. 2, the manufacturing process of the semiconductor device is, firstly, forming a drift region 112 in a substrate 110. Thereafter, forming a first shield region 120 in the drift region 112. The first shield region 120 can use diffusion, ion implantation or any suitable method to form.

Thereafter, forming a second shield region 130 in the drift region 112, in which a carrier concentration of the first shield region 120 is greater than a carrier concentration of the second shield region 130. In some embodiments, the carrier concentration of the first shield region 120 is about twice as the carrier concentration of the second shield regions 130. For example, the carrier concentration of the second shield region is in a range of 1×10¹⁷ cm⁻³ to 1×10¹⁹ cm⁻³, and the carrier concentration of the first shield region is in a range of 2×10¹⁷ cm⁻³ to 2×10¹⁹ cm⁻³. The formation of the second shield region 130 can use diffusion, ion implantation or any suitable method. Moreover, a portion 124 of the first shield region 120 extends under the bottom surface 131 of the second shield region 130.

Refer to FIG. 2, thereafter, forming a well region 140 in the drift region 112, in which the carrier concentration of the second shield region 130 is greater than a carrier concentration of the well region 140. For example, the carrier concentration of the well region 140 is in a range of 5×10¹⁶ cm⁻³ to 1×10¹⁸ cm⁻³. In other words, in some embodiments, the doping concentration of the first shield region 120 is greater than the doping concentration of the second shield region 130, and the doping concentration of the second shield region 130 is greater than the doping concentration of the well region 140. In some embodiments, the first shield region 120, the second shield region 130 and the well region can have a same first conductivity type, such as P type area, and can include P type dopant. The formation of the well region 140 can use diffusion, ion implantation or any suitable method. Moreover, a first portion 132 of the second shield region 130 is located between the well region 140 and the first shield region 120.

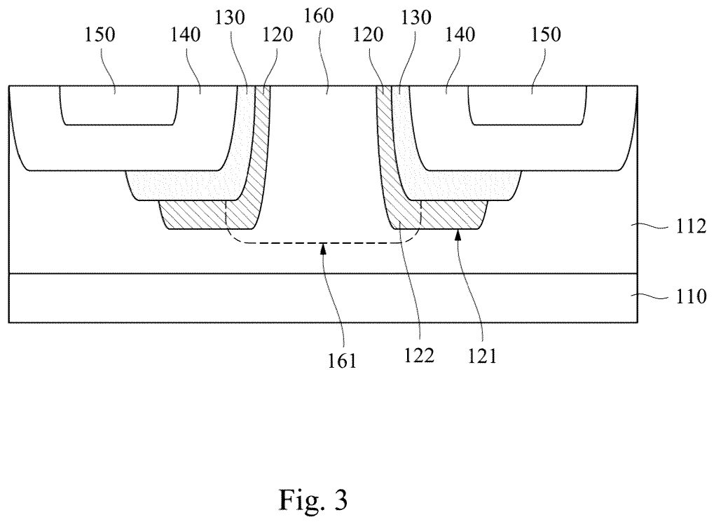

Refer to FIG. 3, thereafter, forming a source region 150 in the well region 140. The formation of the source region 150 can use diffusion, ion implantation or any suitable method. Thereafter, forming a junction gate field-effect transistor (JFET) region 160 in the drift region 112. In some embodiments, the bottom surface 161 of the JFET region 160 is lower than the bottom surface 121 of the first shield region 120, and a first portion 122 of the first shield region is located between the well region 140 and the JFET region 160. In some embodiment, the drift region 112 and the JFET region 160 can have a same second conductivity type, such as N type area, and can includes N type dopant.

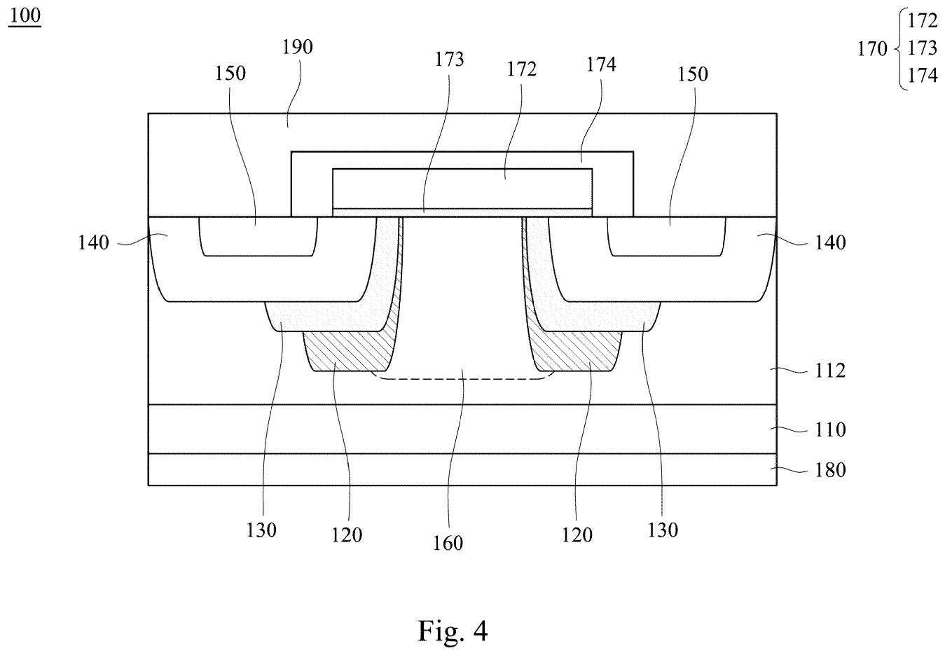

Refer to FIG. 4, thereafter, forming a gate structure 170 on the drift region 112. The gate structure 170 includes a gate conducting layer 172 and a gate dielectric layer 174. In some embodiments, the gate dielectric layer 174 will evenly cover on the drift region 112 by depositing or other suitable method. Thereafter, depositing the gate conducting layer 172. Thereafter, patterning the gate dielectric layer 174 and the gate conducting layer 172 to form the gate structure 170. In some embodiments, the gate conducting layer 172 includes a conducting material, such as metal or poly silicon, but not limited to these. The gate dielectric layer 174 includes dielectric materials, such as silicon dioxide (SiO₂), aluminum oxide (Al₂O₃) or high-k dielectric material, but not limited to these.

Thereafter, forming a dielectric layer 173 to cover the gate structure 170. In some embodiments, the dielectric layer 173 can include suitable dielectric materials, such as silicon oxide, silicon nitride, or the like.

Thereafter, forming a source pad 190 on the gate structure 170 and the drift region 112. In some embodiments, the source pad 190 includes a conducting material, such as metal or poly silicon, but not limited to these. Thereafter, forming a drain pad 180 on a side of the substrate 110 opposite to the drift region 112. After that, the semiconductor device 100 is complete. In some embodiments, the drain pad 180 includes a conducting material, such as metal or poly silicon, but not limited to these.

Since there are shield regions (such as, first shield region 120, second shield region 130) between the JFET region 160 and well region 140, the problem of drain-source leakage current can be significantly solved, which decrease the effect of the drain-source leakage current on the power consumption of the device.

In the following description, different types of semiconductor device are described.

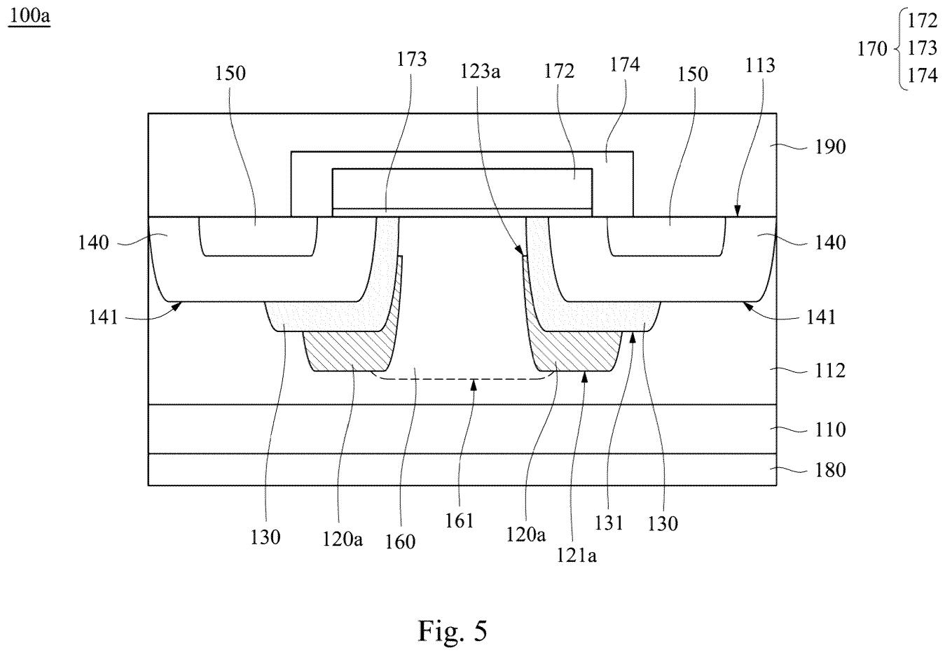

FIG. 5 is a cross-sectional view of a semiconductor device 100a according to another embodiment of the present disclosure. Refer to FIG. 5, a semiconductor device 100a includes a substrate 110, a gate structure 170, a plurality of well region 140, a plurality of first shield region 120a, a plurality of second shield region 130, a JFET region 160 and a source region 150. The gate structure 170 is located on the substrate 110. The well region 140 is located in the substrate 110 and at two sides of the gate structure 170. The second shield region 130 is located in the substrate 110 and at two sides of the gate structure 170, in which a bottom surface 131 of the second shield region 130 is lower than a bottom surface 141 of the well region 140 and a carrier concentration of the second shield region 130 is greater than a carrier concentration of the well region 140. The first shield region 120a is located in the substrate 110 and at two sides of the gate structure 170, in which a bottom surface 121a of the first shield region 120a is lower than a bottom surface 131 of the second shield region 130 and a carrier concentration of the first shield region 120a is greater than a carrier concentration of the second shield region 130. The JFET region 160 is located in the substrate 110, in which a bottom surface 161 of the JFET region 160 is lower than a bottom surface 121a of the first shield region 120a. The source region 150 is adjacent to the well region 140. The gate structure 170 includes a gate conducting layer 172, a dielectric layer 173 and a gate dielectric layer 174. Moreover, the semiconductor device 100a also includes a drain pad 180 and a source pad 190. The drain pad is located on a surface of the substrate 110 opposite to the drift region 112. The source pad 190 is located on the drift region 112 and the gate structure 170. Moreover, in the present embodiment, the top surface 123a of the first shield region 120a is lower than the top surface 113 of the substrate 110.

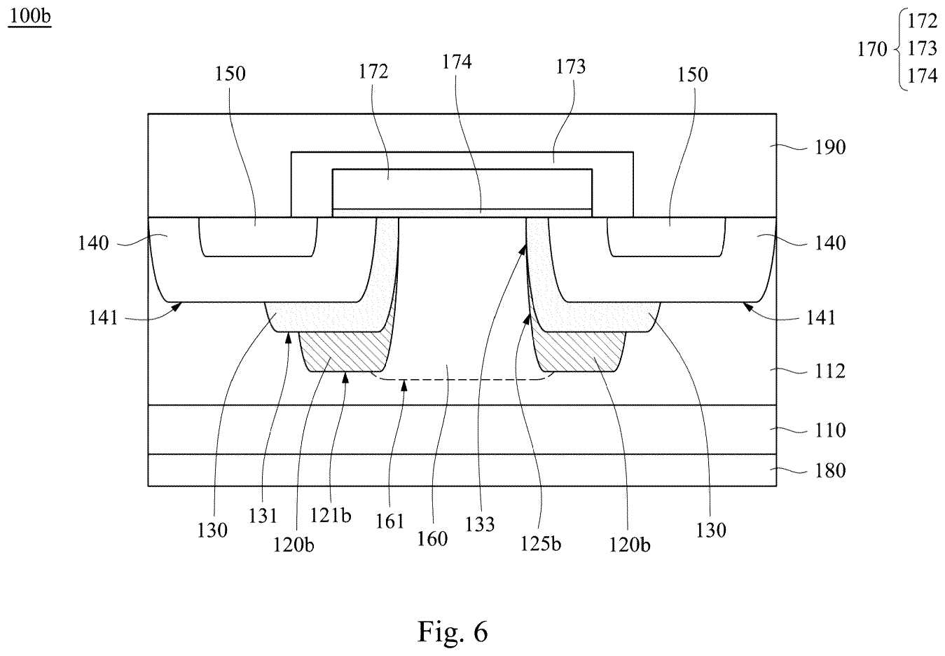

FIG. 6 is a cross-sectional view of a semiconductor device 100b according to yet another embodiment of the present disclosure. Refer to FIG. 6, a semiconductor device 100b includes a substrate 110, a gate structure 170, a plurality of well region 140, a plurality of first shield region 120b, a plurality of second shield region 130, a JFET region 160 and a source region 150. The gate structure 170 is located on the substrate 110. The well region 140 is located in the substrate 110 and at two sides of the gate structure 170. The second shield region 130 is located in the substrate 110 and at two sides of the gate structure 170, in which a bottom surface 131 of the second shield region 130 is lower than a bottom surface 141 of the well region 140 and a carrier concentration of the second shield region 130 is greater than a carrier concentration of the well region 140. The first shield region 120b is located in the substrate 110 and at two sides of the gate structure 170, in which a bottom surface 121b of the first shield region 120b is lower than a bottom surface 131 of the second shield region 130 and a carrier concentration of the first shield region 120b is greater than a carrier concentration of the second shield region 130. The JFET region 160 is located in the substrate 110, in which a bottom surface 161 of the JFET region 160 is lower than a bottom surface 121b of the first shield region 120b. The source region 150 is adjacent to the well region 140. The gate structure 170 includes a gate conducting layer 172, a dielectric layer 173 and a gate dielectric layer 174. Moreover, the semiconductor device 100b also includes a drain pad 180 and a source pad 190. The drain pad is located on a surface of the substrate 110 opposite to the drift region 112. The source pad 190 is located on the drift region 112 and the gate structure 170. Moreover, in the present embodiment, a sidewall 125b of the first shield region 120b is align to a sidewall 133 of the second shield region 130.

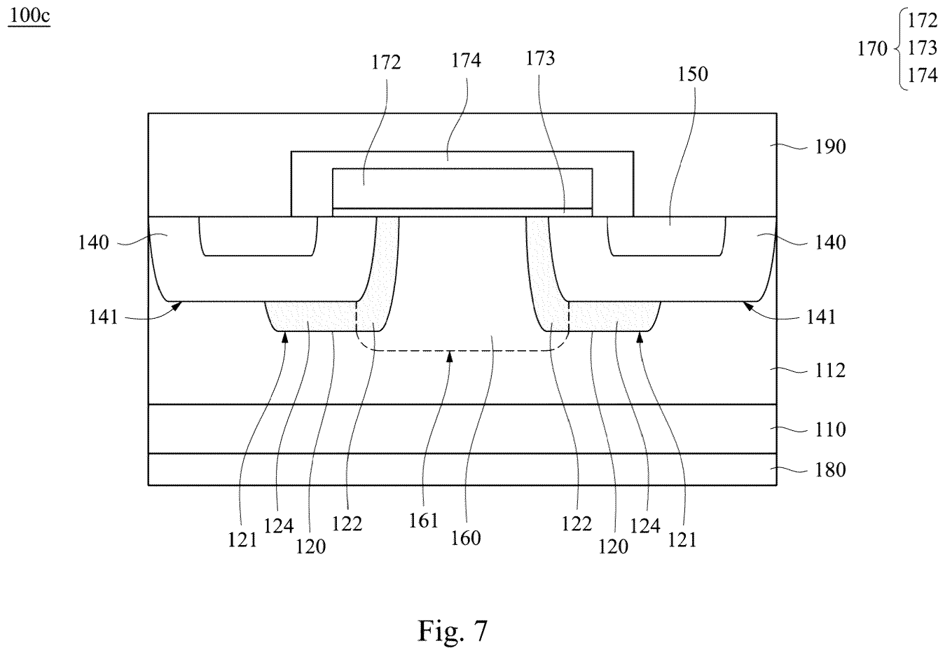

FIG. 7 is a cross-sectional view of a semiconductor device 100c according to yet another embodiment of the present disclosure. Refer to FIG. 7, a semiconductor device 100c includes a substrate 110, a drift region 112, a well region 140, a first shield region 120, a JFET region 160, a source region 150 and a gate structure 170. The drift region 112 is located in the substrate 110. The well region 140 is located in the drift region 112. The first shield region 120 is located in the drift region 112, in which a bottom surface 121 of the first shield region 120 is lower than a bottom surface 141 of the well region 140 and a carrier concentration of the first shield region 120 is greater than a carrier concentration of the well region 140. The JFET region 160 is located in the drift region 112, in which a bottom surface 161 of the JFET region 160 is lower than a bottom surface 121 of the first shield region 120. A first portion 122 of the first shield region 120 is located between the well region 140 and the JFET region 160. A second portion 124 of the first shield region 120 extends to the bottom surface 141 of the well region 140. The source region 150 is adjacent to the well region 140. The gate structure 170 is located on the drift region 112. The gate structure 170 includes a gate conducting layer 172, a dielectric layer 173 and a gate dielectric layer 174. Moreover, the semiconductor device 100b also includes a drain pad 180 and a source pad 190. The drain pad is located on a surface of the substrate 110 opposite to the drift region 112. The source pad 190 is located on the drift region 112 and the gate structure 170.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a drift region located in the substrate;
a well region located in the drift region;
a first shield region located in the drift region, wherein a bottom surface of the first shield region is lower than a bottom surface of the well region and a carrier concentration of the first shield region is greater than a carrier concentration of the well region;
a junction gate field-effect transistor (JFET) region located in the drift region, wherein a bottom surface of the JFET region is lower than a bottom surface of the first shield region, a first portion of the first shield region is located between the well region and the JFET region;
a source region adjacent to the well region; and
a gate structure located on the drift region.

2. The semiconductor device of claim 1, wherein the carrier concentration of the first shield region is in a range of 1×10¹⁷ cm⁻³ to 1×10¹⁹ cm⁻³.

3. The semiconductor device of claim 1, wherein the carrier concentration of the well region is in a range of 5×10¹⁶ cm⁻³ to 1×10¹⁸ cm⁻³.

4. The semiconductor device of claim 1, wherein a second portion of the first shield region extends to the bottom surface of the well region.

5. The semiconductor device of claim 1, wherein a sidewall of the first shield region is align to a sidewall of the well region.

6. The semiconductor device of claim 1, further comprising:
a second shield region located in the drift region.

7. The semiconductor device of claim 1, further comprising:
a drain pad located on a side of the substrate opposite to the gate structure.

8. The semiconductor device of claim 1, further comprising:
a source pad located on the drift region and the gate structure.

9. A semiconductor device, comprising:
a substrate;
a gate structure located on the substrate;
a plurality of well region located in the substrate and at two sides of the gate structure;
a plurality of first shield region located in the substrate and at two sides of the gate structure, wherein a bottom surface of the first shield region is lower than a bottom surface of the well region and a carrier concentration of the first shield region is greater than a carrier concentration of the well region;
a plurality of second shield region located in the substrate and at two sides of the gate structure, wherein a bottom surface of the second shield region is lower than a bottom surface of the first shield region and a carrier concentration of the second shield region is greater than a carrier concentration of the first shield region;
a junction gate field-effect transistor (JFET) region located in the substrate, wherein a bottom surface of the JFET region is lower than a bottom surface of the second shield region; and
a source region adjacent to the well region.

10. The semiconductor device of claim 9, wherein the carrier concentration of the first shield regions is in a range of 1×10¹⁷ cm⁻³ to 1×10¹⁹ cm⁻³.

11. The semiconductor device of claim 9, wherein the carrier concentration of the second shield regions is in a range of 2×10¹⁷ cm⁻³ to 2×10¹⁹ cm⁻³.

12. The semiconductor device of claim 9, wherein the carrier concentration of the second shield regions is about twice as the carrier concentration of the first shield regions.

13. The semiconductor device of claim 9, wherein a sidewall of one of the second shield regions is align to a sidewall of one of the first shield regions.

14. The semiconductor device of claim 9, wherein a top surface of one of the second shield regions is lower than a top surface of the substrate.

15. The semiconductor device of claim 14, wherein the top surface of the second shield region is lower than a top surface of one of the first shield regions.

16. A manufacturing method of a semiconductor device, comprising:
forming a drift region in a substrate;
forming a first shield region in the drift region;
forming a second shield region in the drift region, wherein a carrier concentration of the first shield region is greater than a carrier concentration of the second shield region;
forming a well region in the drift region, wherein the carrier concentration of the second shield region is greater than a carrier concentration of the well region;
forming a source region in the well region;
forming a junction gate field-effect transistor (JFET) region in the drift region; and
forming a gate structure on the drift region.

17. The manufacturing method of the semiconductor device of claim 16, wherein the carrier concentration of the second shield region is in a range of 1×10¹⁷ cm⁻³ to 1×10¹⁹ cm⁻³.

18. The manufacturing method of the semiconductor device of claim 16, wherein the carrier concentration of the first shield region is in a range of 2×10¹⁷ cm⁻³ to 2×10¹⁹ cm⁻³.

19. The manufacturing method of the semiconductor device of claim 16, wherein the carrier concentration of the well region is in a range of 5×10¹⁶ cm⁻³ to 1×10¹⁸ cm⁻³.

20. The manufacturing method of the semiconductor device of claim 16, wherein forming a second shield region in the drift region such that a sidewall of a portion of the second shield region is align to a sidewall of the first shield region.
